(19) United States
(12) Patent Application Publication
(10) Pub. No.: US 2020/0388651 A1
(43) Pub. Date: Dec. 10, 2020

(54) DISPLAY PANEL, METHOD OF FABRICATING THE SAME AND DISPLAY DEVICE INCLUDING THE SAME

(71) Applicant: Seloco InT, Inc., Seoul (KR)

(72) Inventor: Nam Jea WOO, Seoul (KR)

(21) Appl. No.: 16/432,697

(22) Filed: Jun. 5, 2019

(51) Int. Cl. H01L 27/32; H01L 51/52; H01L 51/50

(52) U.S. Cl. CPC H01L 27/322; H01L 51/5278; H01L 51/5092; H01L 51/5056; H01L 51/5072; H01L 51/5036

(57) ABSTRACT

A display panel includes: first and second substrates including a plurality of pixels and spaced apart from each other; a plurality of light emitting layers emitting a light in the plurality of pixels, respectively, over an inner surface of the first substrate; an auxiliary layer for an optical cavity in at least one of the plurality of pixels between the first substrate and the plurality of light emitting layers; a plurality of color filters in at least one of the plurality of pixels on an inner surface of the second substrate; and a quantum dot color converting layer in at least one of the plurality of pixels on the plurality of color filters, the quantum dot color converting layer converting a color of the light from the plurality of light emitting layers.

### BACKGROUND OF THE INVENTION

### Field of the Invention

The present invention relates to a display panel, a method of fabricating the display panel and a display device including the display panel, and more particularly, to a flat display panel including a light emitting diode and a quantum dot color converting layer, a method of fabricating the flat display panel and a display device including the flat display panel.

### Discussion of the Related Art

Recently, various flat panel displays (FPDs) have been developed. The slim type FPDs may be classified into a liquid crystal display (LCD) device, an electroluminescent display (ELD) device, an electrophoretic display (EPD) device, a plasma display panel (PDP) device, a field emission display (FED) device, an electrowetting display (EWD) device and an organic light emitting diode (OLED) display device according to a display panel. The FPDs may include a flat display panel displaying an image as an essential element.

Since the LCD device includes a non-emissive type display panel, a backlight unit is required. The LCD device displays an image by passing or blocking a light emitted from the backlight unit by a pixel using a liquid crystal panel. Since the LCD device does not display a real black, a contrast ratio of the LCD device is reduced. In addition, since a liquid crystal has a low response speed, the LCD device has a limit in displaying a moving image of a high resolution.

Since the OLED display device of an emissive type does not require an additional light source, the OLED display device has a light weight and a thin profile. The OLED display device has a superiority in a viewing angle and a contrast ratio and an advantage in a power consumption as compared with the LCD device. Further, the OLED display device may be driven with a direct current (DC) low voltage and may have a fast response speed. As a result, the OLED display device has been the subject of recent research in substitution for the LCD device.

The OLED display device may be classified into an RGB OLED display device and a white OLED display device according to a color reproduction method.

The RGB OLED display device uses light emitting diodes (LEDs) emitting red, green and blue colored lights to display a color. In the RGB OLED display device, since lights emitted from the LEDs are directly used, a light usage efficiency increases. However, in the RGB OLED display device, since the display panel is fabricated by patterning the LED in each pixel, the fabrication process has a limit for a large sized substrate. Further, the RGB OLED display device has a problem such that a material development and a structure design for each of R, G and B LEDs are required.

The white OLED display device uses a white LED as a light source and displays an image by using red, green and blue color filters. In the white OLED display device, since one kind of LED is used, a fabrication process is simplified. However, in the white OLED display device, since some of a white light emitted from the white LED passes through the color filters and the other of the white light is absorbed by the color filters, a light efficiency is reduced.

### SUMMARY OF THE INVENTION

Accordingly, the present invention is directed to a display panel, a fabrication method of the display panel and a display device including the display panel that substantially obviate one or more of the problems due to limitations and disadvantages of the related art.

An object of the present invention is to provide a display panel where a light usage efficiency and a color reproducibility are improved, a method of fabricating the display panel and a display device including the display panel.

Additional features and advantages of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described herein, a display panel includes: first and second substrates including a plurality of pixels and spaced apart from each other; a plurality of light emitting layers emitting a light in the plurality of pixels, respectively, over an inner surface of the first substrate; an auxiliary layer for an optical cavity in at least one of the plurality of pixels between the first substrate and the plurality of light emitting layers; a plurality of color filters in at least one of the plurality of pixels on an inner surface of the second substrate; and a quantum dot color converting layer in at least one of the plurality of pixels on the plurality of color filters, the quantum dot color converting layer converting a color of the light from the plurality of light emitting layers.

In another aspect, a method of fabricating a display panel includes: forming a yellow light emitting layer in first, second and third pixels on a first substrate; removing the yellow light emitting layer in the first pixel by a laser beam; forming a blue light emitting layer in the first pixel on the first substrate and in the second and third pixels on the yellow light emitting layer, the yellow light emitting layer and the blue light emitting layer constituting a white light emitting layer in the second and third pixels; forming an auxiliary layer for an optical cavity between the first substrate and blue light emitting layer in the first pixel or between the first pixel and the yellow light emitting layer in the third pixel; forming a green color filter and a red color filter in the second and third pixels, respectively, on a second substrate; forming a green quantum dot color converting layer and a red quantum dot color converting layer on the green color filter and the red color filter, respectively; and attaching the first and second substrates.

In another aspect, a display device includes: a display part including a display panel, wherein the display panel includes: first and second substrates including a plurality of pixels and spaced apart from each other; a plurality of light emitting layers emitting a light in the plurality of pixels, respectively, over an inner surface of the first substrate; an auxiliary layer for an optical cavity in at least one of the plurality of pixels between the first substrate and the plurality of light emitting layers; a plurality of color filters in at least one of the plurality of pixels on an inner surface of the second substrate; and a quantum dot color converting layer in at least one of the plurality of pixels on the plurality of color filters, the quantum dot color converting layer converting a color of the light from the plurality of light emitting layers; an image part processing an image signal for the display part; and a control part controlling the image part such that the display part displays an image based on the image signal.

In another aspect, a display panel includes: first and second substrates facing and spaced apart from each other, the first and second substrates including first, second and third pixels corresponding to blue, green and red colors, respectively; a yellow light emitting layer in each of the second and third pixels on an inner surface of the first substrate; a blue light emitting layer in the first pixel on the inner surface of the first substrate and in each of the second and third pixels on the yellow light emitting layer; a green color filter and a red color filter in the second and third pixels, respectively, on an inner surface of the second substrate; a green quantum dot color converting layer in the second pixel on the green color filter and a red quantum dot color converting layer in the third pixel on the red color filter.

It is to be understood that both the foregoing general description and the following detailed description are explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a cross-sectional view showing a display panel according to a first embodiment of the present disclosure;

FIG. 2A is a cross-sectional view showing a blue light emitting layer of a display panel according to a first embodiment of the present disclosure;

FIG. 2B is an equivalent circuit diagram showing a blue light emitting diode including a blue light emitting layer of a display panel according to a first embodiment of the present disclosure;

FIG. 3 is a cross-sectional view showing a display panel according to a second embodiment of the present disclosure;

FIGS. 4A to 4E are cross-sectional views showing a method of fabricating a display panel according to a second embodiment of the present disclosure; and

FIG. 5 is a view showing a display device including a display panel according to first and second embodiments of the present disclosure.

### DETAILED DESCRIPTION OF THE EMBODIMENTS

Reference will now be made in detail to the present disclosure, examples of which are illustrated in the accompanying drawings.

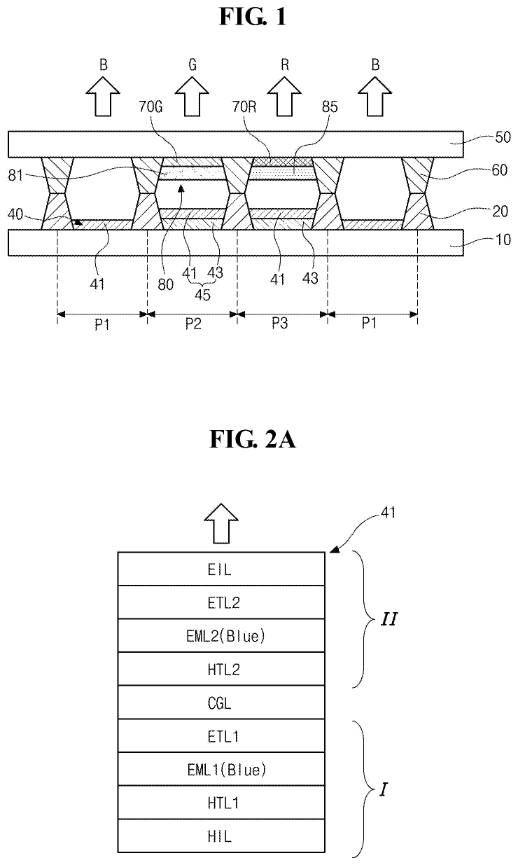

FIG. 1 is a cross-sectional view showing a display panel according to a first embodiment of the present disclosure.

In FIG. 1, a display panel according to a first embodiment of the present disclosure includes first and second substrates 10 and 50 facing and spaced apart from each other, a light emitting layer 40 on an inner surface of the first substrate 10, a color filter layer including color filters 70G and 70R on an inner surface of the second substrate 50 and a quantum dot color converting layer 80 on the color filter layer.

The first and second substrates 10 and 50 include a plurality of pixels emitting lights of different colors corresponding to different wavelengths to display a color image. For example, the plurality of pixels may include first, second and third pixels P1, P2 and P3 emitting lights of blue, green and red colors B, G and R.

Although not shown, a first electrode for supplying a first voltage is disposed in each pixel on the inner surface of the first substrate 10, and the light emitting layer 40 is disposed on the first electrode. The first electrode may be one of an anode and a cathode.

A plurality of dividers are disposed between the first and second substrates 10 and 50. The plurality of dividers classify a space between the first and second substrates 10 and 50 into the pixels and support a gap between the first and second substrates 10 and 50. The plurality of dividers may have a lattice shape or a matrix shape in a plan view. Each of the plurality of dividers may include a first divider 20 on the inner surface of the first substrate 10 and a second divider 60 on the inner surface of the second substrate 50. The first and second dividers 20 and 60 face each other and are disposed at corresponding portions. The first and second dividers 20 and 60 may contact each other.

The first dividers 20 classify the light emitting layer 40 into the pixels, and the light emitting layer 40 is disposed in the space between the first dividers 20 (inside the first divider 20). The light emitting layer 40 is disposed in each pixel on the inner surface of the first substrate 10 and emits a light of a wavelength corresponding to each pixel. For example, the light emitting layer 40 may include a blue light emitting layer 41 and a white light emitting layer 45 according to a color property of the first, second and third pixels P1, P2 and P3. The first pixel P1 may include the blue light emitting layer 41 to emit a light of a blue color B. The second pixel P2 may include the white light emitting layer 45, a green quantum dot color converting layer 81 and the green color filter 70G to emit a light of a green color G. The third pixel P3 may include the white light emitting layer 45, a red quantum dot color converting layer 85 and the red color filter 70R to emit a light of a red color R.

The white light emitting layer 45 emitting a light of a white color may include a yellow light emitting layer 43 emitting a light of a yellow color and the blue light emitting layer 41 emitting a light of a blue color B.

The light emitting layer 40 of an active element includes an organic material layer emitting a light controlled by pixel. Since the light emitting layer 40 is turned off to display a black, a real black image may be displayed by turning off the plurality of pixels. When an image different from the black image is displayed, only the corresponding pixels are driven.

Although not shown, a second electrode for supplying a second voltage is disposed on the light emitting layer 40. The second electrode may be one of an anode and a cathode and may be disposed in a whole of the plurality of pixels.

The blue light emitting layer 41 may directly emit a light of a blue color toward an exterior or may emit a light of a predetermined color such as a green color and a red color toward an exterior by a combination with the yellow light emitting layer 43 and the quantum dot color converting layer 80.

A lifetime of an organic material for emitting a light of a blue color is shorter than a lifetime of an organic material for emitting a light of a red color and a green color. As a result, the blue light emitting layer 41 may be formed to have a tandem structure where two light emitting diodes (LEDs) are connected in series to reduce a current density which is a total current per a unit area.

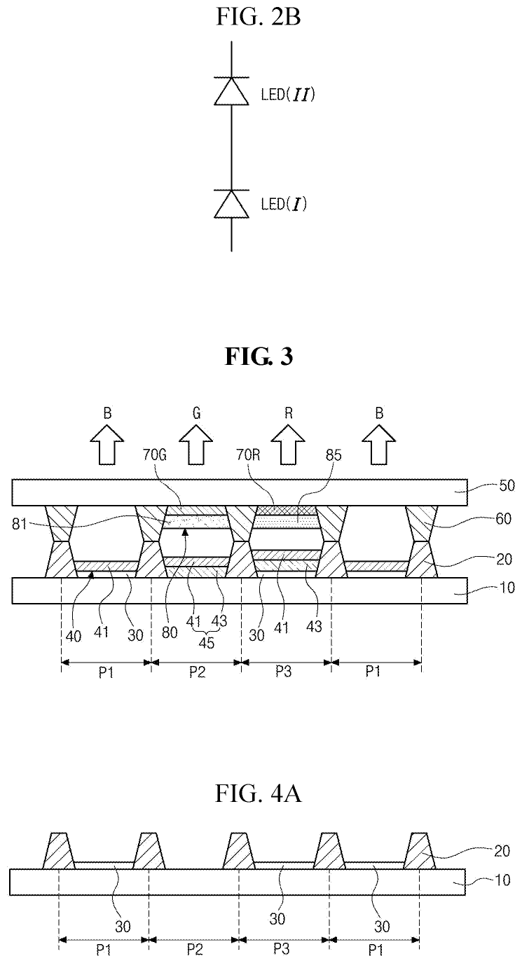

FIG. 2A is a cross-sectional view showing a blue light emitting layer of a display panel according to a first embodiment of the present disclosure, and FIG. 2B is an equivalent circuit diagram showing a blue light emitting diode including a blue light emitting layer of a display panel according to a first embodiment of the present disclosure.

In FIGS. 2A and 2B, the blue light emitting layer 41 includes a first emitting layer I, a charge generating layer CGL and a second emitting layer II. Each of the first and second emitting layers I and II may constitute a light emitting diode (LED) generating and emitting a light, and the two LEDs of the first and second emitting layers I and II may be connected to each other in series. The blue light emitting layer 41 may emit a light of a blue color through a top surface of the second emitting layer II along a direction of an arrow.

The first emitting layer I may include a hole injecting layer HIL, a first hole transporting layer HTL1, a first emitting material layer EML1 emitting a light of a blue color and a first electron transporting layer ETL1 sequentially on the inner surface of the first substrate 10. The charge generating layer CGL is disposed on the first emitting layer I to connect the first and second emitting layers I and II in series. The second emitting layer II may include a second hole transporting layer HTL2, a second emitting material layer EML2 emitting a light of a blue color, a second electron transporting layer ETL2 and an electron injecting layer EIL sequentially on the charge generating layer CGL.

The blue light emitting layer 41 has a tandem structure including at least two emitting material layers, and the first and second emitting layers I and II are connected in series through the charge generating layer CGL instead of an additional electrode layer. As a result, a lifetime of the blue light emitting layer 41 is extended, and deterioration of the blue light emitting layer 41 is prevented. In addition, since the light is emitted through the top surface of the second emitting layer II, an emitting area of the blue light emitting layer 41 is enlarged.

Referring again to FIG. 1, the quantum dot color converting layer 80 is disposed in a predetermined pixel on the color filter layer to emit a light of a predetermined color. For example, the quantum dot color converting layer 80 may be disposed in the pixel corresponding to a blue color and/or a red color on the color filter layer. The quantum dot color converting layer 80 may be disposed in the pixel correspond to the white light emitting layer 45 and may convert the incident light of a white color from the white light emitting layer 45 into a light of a green color or a red color to emit the light of a green color or a red color. The quantum dot color converting layer 80 may include a green quantum dot converting layer 81 and a red quantum dot color converting layer 85. As a result, the light of a whit color from the white light emitting layer 45 may be converted into a light of a green color and a red color through the green quantum dot converting layer 81 and the red quantum dot color converting layer 85, respectively, and the light of the green color and the red color is emitted to the green color filter 70G and the red color filter 70R, respectively.

The color filter layer is disposed in a predetermined pixel on the inner surface of the second substrate 50 such that the color filter layer is dispose between the second substrate 50 and the quantum dot color converting layer 80. For example, the color filter layer may include the green color filter 70G in the pixel corresponding to a green color and the red color filter 70R in the pixel corresponding to a red color. The color filter layer may display a color image by selectively transmitting a light of a predetermined color. The green color filter 70G may transmit a light of a green color from the green quantum dot color converting layer 81 and may absorb a light of a color different from the green color to display a green image. The red color filter 70R may transmit a light of a red color from the red quantum dot color converting layer 85 and may absorb a light of a color different from the red color to display a red image.

In the first pixel P1 corresponding to a blue color, the blue light emitting layer 41 is disposed and the yellow light emitting layer the quantum dot color converting layer and the color filter layer are not disposed. As a result, a light transmittance of the first pixel P1 increases over about 95% and a light efficiency is improved. In addition, since the green color and the red color are displayed by combination of the quantum dot color converting layer 80 and the color filter layer on the white light emitting layer 45, a light efficiency of the green color and the red color is improved.

Since the display panel displays an image using the light emitting layer 40 and the quantum dot color converting layer 80, the structure of the display panel is simplified and the color reproducibility and the light usage efficiency are improved.

FIG. 3 is a cross-sectional view showing a display panel according to a second embodiment of the present disclosure.

In FIG. 3, a display panel according to a second embodiment of the present disclosure includes first and second substrates 10 and 50 facing and spaced apart from each other, a light emitting layer 40 on an inner surface of the first substrate 10, a color filter layer including color filters 70G and 70R on an inner surface of the second substrate 50 and a quantum dot color converting layer 80 on the color filter layer.

Since the first and second substrates 10 and 50, the light emitting layer 40, the quantum dot color converting layer 80 and the color filter layer of the second embodiment have the same structure as the first and second substrates 10 and 50, the light emitting layer 40, the quantum dot color converting layer 80 and the color filter layer of the first embodiment, a detailed illustration will be omitted.

An auxiliary layer 30 may be disposed between the first substrate 10 and the light emitting layer 40 in a predetermined pixel for an optical cavity (microcavity). For example, the auxiliary layer 30 may be disposed between the first substrate 10 and the blue light emitting layer 41 in the first pixel P1 with a predetermined thickness (height), and the auxiliary layer 30 may be disposed between the first substrate 10 and the white light emitting layer 45 in the third pixel P3 with a predetermined thickness (height).

The auxiliary layer 30 may be formed in the first electrode on the first substrate 10 and may include a material having a relatively high refractive index and a relatively high transmittance. For example, the auxiliary layer 30 may include a transparent conductive material such as indium tin oxide (ITO) and indium zinc oxide (IZO). When the auxiliary layer 30 is disposed in the first and third pixels P1 and P3, the optical cavity is constituted between the first substrate 10 and the blue light emitting layer 41 and between the first substrate 10 and the white light emitting layer 45.

Since the optical cavity effect increases due to the auxiliary layer 30, a color reproducibility is improved. When a color image is displayed by combination of the light of the blue, green and red colors of the first, second and third pixels P1, P2 and P3, a non-uniformity in color balance may occur due to a property of the light emitting layer 40, the quantum dot color converting layer 80 and the color filter layer. In the display panel according to the second embodiment, the non-uniformity in color balance may be improved by adjusting the thickness of the auxiliary layer 30.

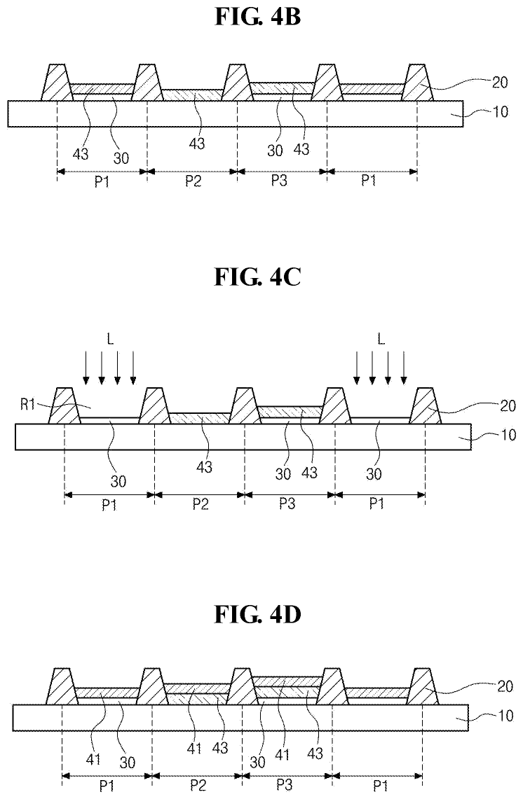

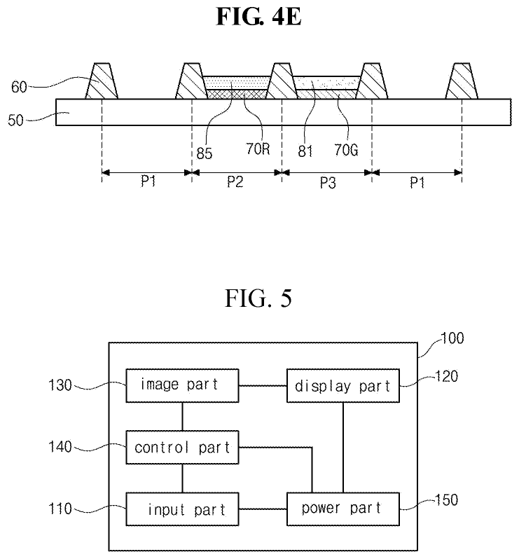

FIGS. 4A to 4E are cross-sectional views showing a method of fabricating a display panel according to a second embodiment of the present disclosure.

In FIGS. 4A to 4E, the display panel may be fabricated through a process of forming a lower unit, a process of forming an upper unit and a process of attaching the lower and upper units. The lower unit including the first substrate 10 and the light emitting layer 40 is completed through the process of FIGS. 4A to 4D, and the upper unit including the second substrate 50, the color filter layer and the quantum dot color converting layer 80 is completed through the process of FIG. 4E. The display panel of FIG. 3 is fabricated by attaching the lower and upper units such that the light emitting layer 40 and the quantum dot color converting layer 80 face into each other.

In FIG. 4A, the first electrode (not shown) is formed in each of the first, second and third pixels P1, P2 and P3 on the first substrate 10, and the plurality of first dividers 20 are formed at a border portion of the first, second and third pixels P1, P2 and P3 on the first substrate 10. The plurality of first dividers 20 may classify the first substrate 10 into the first, second and third pixels P1, P2 and P3 and may have a predetermined height.

The auxiliary layer 30 is formed in at least one of the first, second and third pixels P1, P2 and P3 on the first substrate 10 for the optical cavity. The auxiliary layer 30 may be formed in the first electrode on the first substrate 10 and may be disposed in the first and third pixels P1 and P3 corresponding to the blue and red colors, respectively, with a predetermined thickness.

In FIG. 4B, the yellow light emitting layer 43 emitting a light of the yellow color is formed in each of the first, second and third pixels P1, P2 and P3 on the first substrate 10 and the auxiliary layer 30 through an evaporation method, a coating method or a deposition method.

In FIG. 4C, the yellow light emitting layer 43 in the first pixel P1 corresponding to the blue color is removed through a laser patterning method. Since the yellow light emitting layer 43 includes a material having a relatively low evaporation point, the yellow light emitting layer 43 may be sublimated even by a relatively low energy. As a result, the yellow light emitting layer 43 may be selectively removed by irradiating a laser beam L onto the first pixel P1 among the plurality of pixels. For example, in the laser patterning method, after a mask exposing the first pixel P1 and covering the second and third pixels P2 and P3 is disposed over the first substrate 10 having the yellow light emitting layer 43, the laser beam may be irradiated onto the first substrate 10 through the mask. In another embodiment, the yellow light emitting layer may be selectively removed through a laser scanning method where the laser beam is scanned across the first substrate 10.

In FIG. 4D, the blue light emitting layer 41 emitting a light of the blue color is formed in each of the first, second and third pixels P1, P2 and P3 on the auxiliary layer 30 and the yellow light emitting layer 43 through an evaporation method, a coating method or a deposition method. The second electrode (not shown) is formed on the blue light emitting layer 41.

Since the blue light emitting layer 41 is formed in the first pixel P1, the first pixel P1 may emit a light of the blue color. Since the blue light emitting layer 41 and the yellow light emitting layer 43 are formed in the second and third pixels P2 and P3, each of the second and third pixels P2 and P3 may emit a light of the white color due to combination of the light of the yellow color from the yellow light emitting layer 43 and the light of the blue color from the blue light emitting layer 41.

Accordingly, the lower unit of the display panel is fabricated through the process of FIGS. 4A to 4D.

In FIG. 4E, the plurality of second dividers 60 are formed at a border portion of the first, second and third pixels P1, P2 and P3 on the second substrate 50. The plurality of second dividers 60 may classify the second substrate 50 into the first, second and third pixels P1, P2 and P3 and may have a predetermined height.

The color filter layer is formed in at least one of the first, second and third pixels P1, P2 and P3 on the second substrate 50. For example, the green color filter 70G and the red color filter 70R may be disposed in the second and third pixels P2 and P3, respectively, on the second substrate 50. The green color filter 70G may transmit a light of the green color from the green quantum dot color converting layer 81, and the red color filter 70R may transmit a light of the red color from the red quantum dot color converting layer 85.

The green quantum dot color converting layer 81 is formed on the green color filter 70G, and the red quantum dot color converting layer 85 is formed on the red color filter 70R.

The upper unit completed through the process of FIG. 4E is attached to the lower unit completed through the process of FIGS. 4A to 4D to complete the display panel of FIG. 3.

In the method of fabricating the display panel according to the present disclosure, since each of the yellow light emitting layer and the blue light emitting layer is formed in the plurality of pixels without a shadow mask or a fine metal mask, the fabrication process is simplified. In the first pixel P1, since the yellow light emitting layer is removed through the laser patterning method, the light from the blue light emitting layer is emitted through the second substrate without passing through the quantum dot color converting layer and the color filter layer and the light transmitting efficiency is maximized.

Further, since the auxiliary layer for the optical cavity is formed in the first and third pixels on the first substrate, the first, second and third pixels have different optical paths. As a result, the non-uniformity in color balance is improved and the color reproducibility is improved.

FIG. 5 is a view showing a display device including a display panel according to first and second embodiments of the present disclosure.

In FIG. 5, a display device 100 including a display panel according to first and second embodiments of the present disclosure includes an input part 110 where a user inputs an order or an information, a display part 120 including the display panel, an image part 130, a control part 140 and a power part 150. The display part 120 may include the display panel of FIGS. 1 to 4E.

The image part 130 may perform an image processing with respect to an image signal for the display part 120 and may input the processed image signal to the display part 120. For example, the image part 130 may be formed as an image processing board in the display device 100. The image processing performed in the image part 110 may include at least one of a decoding, a de-interlacing, a frame refresh rate conversion, a scaling, a noise reduction for improving an image quality and a detail enhancement.

The control part 140 may control the image part 130 such that the display part 120 displays an image based on the image signal. For example, the control part 140 may control the image part 130 such that the image signal is processed according to an input signal through the input part 110 and the display part 120 displays an image corresponding to the processed image signal.

The input part 110 may be formed as a remote control or a touch key and a button on an exterior of the display device 100. Alternatively, the input part 110 may be formed as a portable terminal wirelessly connected to the display device 100.

The power part 150 may supply a power to the input part 110, the display part 1120, the image part 130 and the control part 140.

Consequently, in the display panel according to the present disclosure, since the color filter layer and the quantum dot color converting layer are removed in the blue pixel, the light transmitting efficiency of the blue pixel increases. In addition, since the white light emitting layer, the quantum dot color converting layer and the color filter layer are formed in the green and red pixels, the light transmitting efficiency of the green and red pixels also increases.

Since each of the yellow light emitting layer and the blue light emitting layer is formed in the plurality of pixels without a shadow mask or a fine metal mask, the fabrication process is simplified. In the first pixel P1, the yellow light emitting layer is effectively removed through the laser patterning method.

Since the auxiliary layer for the optical cavity is formed in the first and third pixels on the first substrate, the first, second and third pixels have different optical paths. As a result, the non-uniformity in color balance is improved and the color reproducibility increases.

Since the color image is displayed by using the light emitting layer and the quantum dot color converting layer, the structure of the display panel is simplified. Since the real black image is obtained due to the light emitting layer, the color reproducibility is improved and the power consumption is reduced. Since the quantum dot color converting layer is removed in the blue pixel, the light usage efficiency increases.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display panel comprising:
first and second substrates including a plurality of pixels and spaced apart from each other;
a plurality of light emitting layers emitting a light in the plurality of pixels, respectively, over an inner surface of the first substrate;
an auxiliary layer for an optical cavity in at least one of the plurality of pixels between the first substrate and the plurality of light emitting layers;
a plurality of color filters in at least one of the plurality of pixels on an inner surface of the second substrate; and
a quantum dot color converting layer in at least one of the plurality of pixels on the plurality of color filters, the quantum dot color converting layer converting a color of the light from the plurality of light emitting layers.

2. The display panel of claim 1, wherein the plurality of pixels include first, second and third pixels corresponding to blue, green and red colors, respectively,
wherein the plurality of light emitting layers include a blue light emitting layer in the first pixel and a white light emitting layer in each of the second and third pixels,
wherein the plurality of color filters include a green color filter in the second pixel and a red color filter in the third pixel, and
wherein the quantum dot color converting layer includes a green quantum dot color converting layer in the second pixel and a red quantum dot color converting layer in the third pixel.

3. The display panel of claim 2, wherein the white light emitting layer emitting a light of a white color includes a yellow light emitting layer emitting a light of a yellow color and the blue light emitting layer emitting a light of a blue color.

4. The display panel of claim 2, wherein the blue light emitting layer comprises:
a first emitting layer including a hole injecting layer, a first hole transporting layer, a first emitting material layer emitting a light of a blue color and a first electron transporting layer sequentially on the first substrate;
a charge generating layer on the first emitting layer; and
a second emitting layer including a second hole transporting layer, a second emitting material layer emitting a light of a blue color, a second electron transporting layer and an electron injecting layer sequentially on the charge generating layer,
wherein the first and second emitting layers connected to each other in series, and
wherein the light from the first and second emitting layers is emitted through a top surface of the second emitting layer.

5. The display panel of claim 1, further comprising a plurality of dividers disposed between the first and second substrates and classifying a space between the first and second substrates into the plurality of pixels.

6. The display panel of claim 5, wherein at least one of the plurality of dividers comprises:
a first divider on the inner surface of the first substrate, the first divider classifying the plurality of light emitting layers into the plurality of pixels; and
a second divider on the inner surface of the second substrate, the second divider facing and corresponding to the first divider.

7. A method of fabricating a display panel, comprising:
forming a yellow light emitting layer in first, second and third pixels on a first substrate;
removing the yellow light emitting layer in the first pixel by a laser beam;
forming a blue light emitting layer in the first pixel on the first substrate and in the second and third pixels on the yellow light emitting layer, the yellow light emitting layer and the blue light emitting layer constituting a white light emitting layer in the second and third pixels;
forming an auxiliary layer for an optical cavity between the first substrate and blue light emitting layer in the first pixel or between the first pixel and the yellow light emitting layer in the third pixel;
forming a green color filter and a red color filter in the second and third pixels, respectively, on a second substrate;
forming a green quantum dot color converting layer and a red quantum dot color converting layer on the green color filter and the red color filter, respectively; and
attaching the first and second substrates.

8. The method of claim 7, further comprising forming a first divider at a border portion of the first, second and third pixels on the first substrate.

9. The method of claim 8, further comprising forming a second divider facing and corresponding to the first divider on the second substrate.

10. A display device comprising:
a display part including a display panel,
wherein the display panel comprises:
first and second substrates including a plurality of pixels and spaced apart from each other;
a plurality of light emitting layers emitting a light in the plurality of pixels, respectively, over an inner surface of the first substrate;
an auxiliary layer for an optical cavity in at least one of the plurality of pixels between the first substrate and the plurality of light emitting layers;
a plurality of color filters in at least one of the plurality of pixels on an inner surface of the second substrate; and
a quantum dot color converting layer in at least one of the plurality of pixels on the plurality of color filters, the quantum dot color converting layer converting a color of the light from the plurality of light emitting layers;
an image part processing an image signal for the display part; and
a control part controlling the image part such that the display part displays an image based on the image signal.

11. The display device of claim 10, wherein the display panel further comprises a plurality of dividers disposed between the first and second substrates and classifying a space between the first and second substrates into the plurality of pixels.

12. A display panel comprising:
first and second substrates facing and spaced apart from each other, the first and second substrates including first, second and third pixels corresponding to blue, green and red colors, respectively;
a yellow light emitting layer in each of the second and third pixels on an inner surface of the first substrate;
a blue light emitting layer in the first pixel on the inner surface of the first substrate and in each of the second and third pixels on the yellow light emitting layer;
a green color filter and a red color filter in the second and third pixels, respectively, on an inner surface of the second substrate;
a green quantum dot color converting layer in the second pixel on the green color filter and a red quantum dot color converting layer in the third pixel on the red color filter.

13. The display panel of claim 12, further comprising:
a first electrode between the first substrate and the blue light emitting layer in the first pixel and between the first substrate and the yellow light emitting layer in each of the second and third pixels; and
a second electrode in each of the first, second and third pixels on the blue light emitting layer.

14. The display panel of claim 13, further comprising an auxiliary layer for an optical cavity between the first substrate and the blue light emitting layer in the first pixel and between the first substrate and the yellow light emitting layer in the third pixel.

15. The display panel of claim 14, wherein the auxiliary layer is formed in the first electrode.

16. The display panel of 12, further comprising:
a first divider at a border portion of the first, second and third pixels on the inner surface of the first substrate; and
a second divider at a border portion of the first, second and third pixels on the inner surface of the second substrate.

17. The display panel of claim 16, wherein the yellow light emitting layer and the blue light emitting layer are disposed inside the first divider, and
wherein the green color filter, the red color filter, the green quantum dot color converting layer and the red quantum dot color converting layer are disposed inside the second divider.
